(19) United States
(12) Patent Application Publication
(10) Pub. No.: US 2014/0210062 A1
(43) Pub. Date: Jul. 31, 2014

(54) Leadframe-Based Semiconductor Package Having Terminals on Top and Bottom Surfaces

(71) Applicant: TEXAS INSTRUMENTS INCORPORATED, Dallas, TX (US)

(72) Inventor: Hiroshi Miyazaki, Beppu-City (JP)

(73) Assignee: TEXAS INSTRUMENTS INCORPORATED, Dallas, TX (US)

(21) Appl. No.: 13/751,972

(22) Filed: Jan. 28, 2013

(51) Int. Cl. H01L 23/495; H01L 21/56

(52) U.S. Cl. CPC H01L 23/49575; H01L 21/56
USPC 257/676; 438/123

(57) ABSTRACT

A semiconductor device (100) with a leadframe having first (310) and second (311) leads with central and peripheral ends, the central ends in a first horizontal plane (150). The first leads have peripheral ends (310b) in a second horizontal plane spaced (160) from the first plane and the second leads having peripheral ends in a third horizontal plane (170). A semiconductor chip (101) is connected to the central lead ends. A package (120) encapsulates the chip and the central ends of the first and second leads, leaving the peripheral ends of the first and second leads un-encapsulated, wherein the packaged device has lead ends as terminals on the second and third horizontal plane.

### FIELD OF THE INVENTION

The present invention is related in general to the field of semiconductor devices and processes, and more specifically to leadframe-based semiconductor packages with terminals on top and bottom surfaces, and methods to fabricate these packages.

### DESCRIPTION OF RELATED ART

Semiconductor devices stacked as package-on-package (PoP) products have been introduced in the electronics market more than two decades ago. Stacking packages offers significant advantages by reducing device footprints on circuit boards. Stacking can also be used to improve testability, for instance by permitting separate testing of logic and memory packages before they are assembled as a stacked PoP unit. In other instances, electrical performance may be improved due to shortened interconnections between associated packages. A successful strategy for stacking packages shortens the time-to-market of innovative products by utilizing available devices of various capabilities (such as processors and memory chips) without waiting for a redesign of chips.

In early devices, dual-in-line packages were stacked on top of each other and the leads soldered together. In more recent products, solder balls were introduced to connect the stacked packages mechanically and electrically. Related to the construction of ball grid array (BGA) devices, the commonly used PoP designs use a bottom package with a substrate designed so that its top surface includes the encapsulated chip with a surrounding peripheral area for a number of un-encapsulated metallic contact pads with a solderable surface. A top package has metal pads matching in number and location with the bottom package. The interconnection is preferably accomplished by solder balls (in some devices, bonding wires are used), since the size of solder balls can be selected to fit the size of the contact pads, and the location of the pads can be implemented as a variable into ball deposition computer programs.

The thickness of today's semiconductor PoP products is the sum of the thicknesses of the semiconductor chips, electric interconnections, and encapsulations, which are used in the individual devices constituting the building-blocks of the products. This simple approach, however, is no longer acceptable for the recent applications especially for hand-held wireless equipments, since these applications place new, stringent constraints on the size and volume of semiconductor components used for these applications. The market place is renewing a push to shrink semiconductor devices both in two and in three dimensions, and this miniaturization effort includes packaging strategies for semiconductor devices as well as electronic systems.

Passive electrical components are conventionally placed on PCB's in proximity to the PoP's to minimize parasitic losses and electrical noise. However, this placement still consumes valuable board real estate. Consequently, the market place, searching for methodologies to avoid this loss of board space, recently introduced designs wherein the components are integrated into the structure of multi-metal-level PCB's, preferably close by or directly under the PoP device attached to the board surface. Unfortunately, this integration approach is rather expensive.

### SUMMARY OF THE INVENTION

Analyzing the failures of solder ball interconnections of PoP stacks and of passive components on PCB's, applicant realized that microcracks and delaminations due to thermomechanical stress are a dominant failure mechanism.

Applicant further realized that a wide field of industrial, automotive and consumer applications would open up if the devices for PoPs could safely and cost-effectively be encapsulated in a housing suitable to absorb thermo-mechanical stress and environmental vibrations so prevalent in these applications. When an industrial application of a PoP assembled on a board involves wide and abrupt temperature swings, significant thermo-mechanical stresses are caused due to widely different coefficients of thermal expansion between the silicon-based sensor and the material of the board. These stresses are sufficient to induce microcracks in the attached solder bumps, leading to fracture failures.

In addition, applicant found that valuable real estate of PCB's could be saved and parasitic losses and electrical noise could be significantly reduced if a methodology could be found to assemble passive components vertically on top of PoP's.

Applicant solved the problems of vertically assembling PoP's and passive components and of protecting the PoP against stress-induced failures, when he discovered that an additional lead-forming step early in the process flow for assembling and packaging leadframe-based semiconductor packages provides an additional attachment level for vertically positioning devices on PoP's, while simultaneously maintaining packages with elastic cantilever leads acting as a stress-absorbing compliant barrier between the semiconductor-based chips and the external environment.

In an exemplary embodiment of the modified process flow, a leadframe strip has a plurality of sites with a chip mount pad and elongated first and second leads in a first horizontal plane, and the leads have central ends and peripheral ends. The first leads are bent in a first forming step to position the peripheral ends in a second horizontal plane spaced from the first plane while leaving the central ends in the first plane. Then, a semiconductor chip is assembled onto the chip mount pad of each site; the assembly method may be attaching with sequential wire bonding, or flip-chip assembling. The assembled chip and the central lead ends are encapsulated in a packaging material, while leaving the peripheral lead ends un-encapsulated. Finally, each site is singulated from the strip to form discrete devices.

In another exemplary embodiment, a second forming step bends the un-encapsulated second leads of each device to position the peripheral ends in a third horizontal plane spaced from the first plane, thus creating elastic cantilever leads.

It is a technical advantage of the invention that the method can fabricate devices with cantilever leads protruding from the package, which can accommodate, under a force lying in the plane of the expanding and contracting substrate, elastic bending and stretching beyond the limit of simple elongation based upon inherent lead material characteristics. Such elastic cantilever properties can be achieved by cantilever geometries, which may be selected from straight geometry, curved geometry, toroidal geometry, and multiple-bendings geometry.

It is another technical advantage that electrical components such as capacitors, resistors, and inductors can be vertically assembled onto PoP packages instead of in side-by-side arrangements on PCB's, thereby avoiding the waste of valuable board real estate and the accompanying parasitic interconnection losses and electronic noise.

### BRIEF DESCRIPTION OF THE DRAWINGS

FIG. 1A shows a cross section of an embodiment of a leadframe-based semiconductor package with device terminals on top and bottom of the package.

FIG. 1B depicts a top view of the device of FIG. 1A.

FIG. 2A shows a cross section of another embodiment of a leadframe-based semiconductor package with device terminals on top and bottom of the package.

FIG. 2B illustrates a top view of the device of FIG. 2A.

FIG. 2C depicts a bottom view of the embodiment in FIG. 2A of a leadframe-based semiconductor package with device terminals on top and bottom surfaces.

FIG. 3A is a top view of a device site of an exemplary leadframe strip suitable for starting the bending process steps for fabricating a 16-pin semiconductor device according to the invention.

FIG. 3B shows a top view of a device site of another exemplary leadframe strip suitable for starting the bending process steps for fabricating a 16-pin semiconductor device according to the invention.

FIG. 3C depicts another lead configuration suitable for the bending steps in the fabrication process of devices according to the invention.

FIG. 3D illustrates another lead configuration suitable for the bending steps in the fabrication process of devices according to the invention.

FIGS. 4A to 4I show certain steps of an exemplary process flow for fabricating a leadframe-based semiconductor package with terminals on top and bottom surfaces; the chip is wire-bonded.

FIG. 4A is a cross section of a device site of a starting flat leadframe, with chip pad.

FIG. 4B indicates the process step of placing the leadframe in a lead-bending machine.

FIG. 4C illustrates the process step of bending a set of first leads while leaving a set of second leads flat.

FIG. 4D shows the process step of attaching a chip on the pad using an adhesive compound.

FIG. 4E depicts the process step of connecting the chip to leads by wire bonding.

FIG. 4F shows the process step of encapsulating while leaving the peripheral ends of the first and second leads un-encapsulated.

FIG. 4G illustrates the process steps of trimming the peripheral ends of the first lead ends and bending the peripheral ends of the second leads.

FIG. 4H shows the process step of encapsulating while leaving the peripheral ends of the first and second leads and the chip pad un-encapsulated.

FIG. 4I shows the process step of trimming all peripheral lead ends.

FIGS. 5A to 5I show certain steps of an exemplary process flow for fabricating a leadframe-based semiconductor package with terminals on top and bottom surfaces; the chip is flip-assembled.

FIG. 5A is a cross section of a device site of a starting flat leadframe without chip pad.

FIG. 5B indicates the process step of placing the leadframe in a lead-bending machine.

FIG. 5C illustrates the process step of bending a set of first leads, while leaving a set of second leads flat.

FIG. 5D shows the process step of connecting the chip to leads by flip-assembling using solder bumps

FIG. 5E depicts the process step of underfilling between the solder bumps.

FIG. 5F shows the process step of encapsulating while leaving the peripheral ends of the first and second leads un-encapsulated.

FIG. 5G illustrates the process steps of trimming the peripheral ends of the first lead ends and bending the peripheral ends of the second leads.

FIG. 5H shows the process step of encapsulating while leaving the peripheral ends of the first and second leads and the chip pad un-encapsulated.

FIG. 5I shows the process step of trimming all peripheral lead ends.

### DETAILED DESCRIPTION OF THE PREFERRED EMBODIMENTS

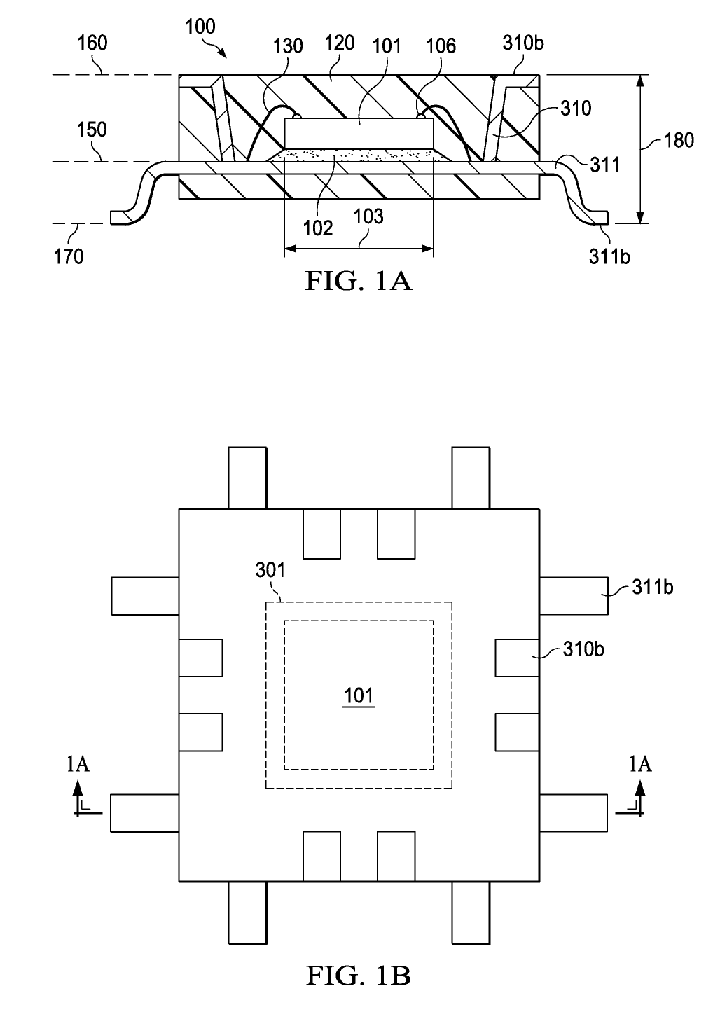

FIG. 1A illustrates an exemplary embodiment of the invention, a packaged device generally designated 100. The device includes a semiconductor chip 101 with terminals 106; chip 101 is embedded in an insulating package 120. A large variety of chips with a wide range of sizes and shapes may be assembled as shown in FIG. 1; an exemplary chip may be square-shaped with a side length 103 of about 4 mm. Device 100 includes a leadframe with elongated leads from the central region of the device to peripheral regions of the device; consequently, each lead has a central lead end and a peripheral lead end. The central lead ends are in the proximity of chip 101. The terminals 106 of chip 101 may be connected by bonding wires 130 (preferably copper or gold) to the central lead ends; alternatively, terminals 106 may be connected by solder bumps to the central lead ends.

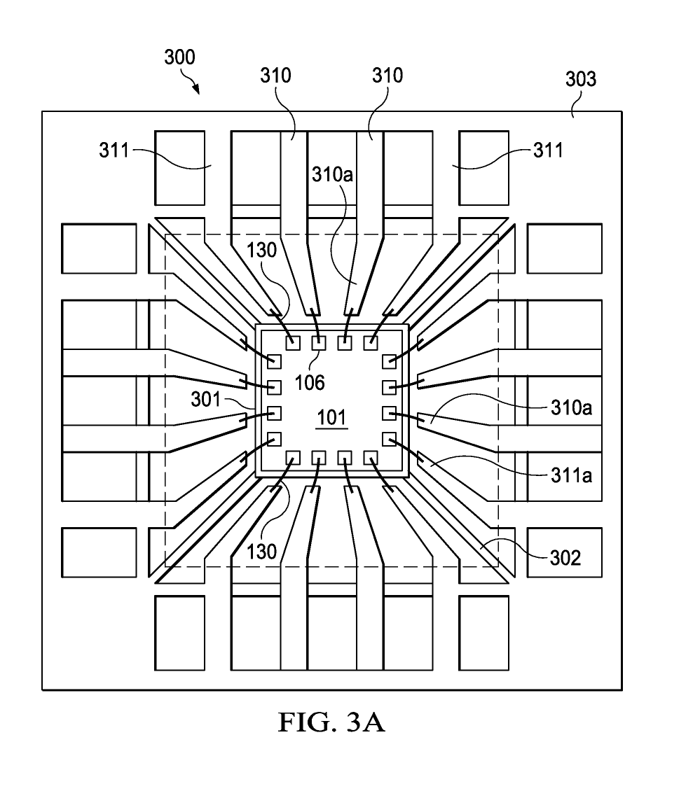

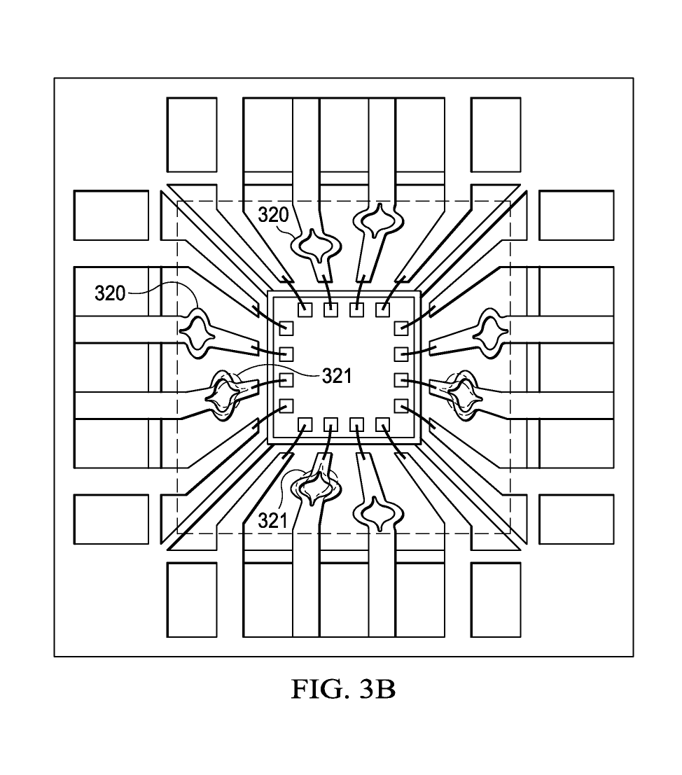

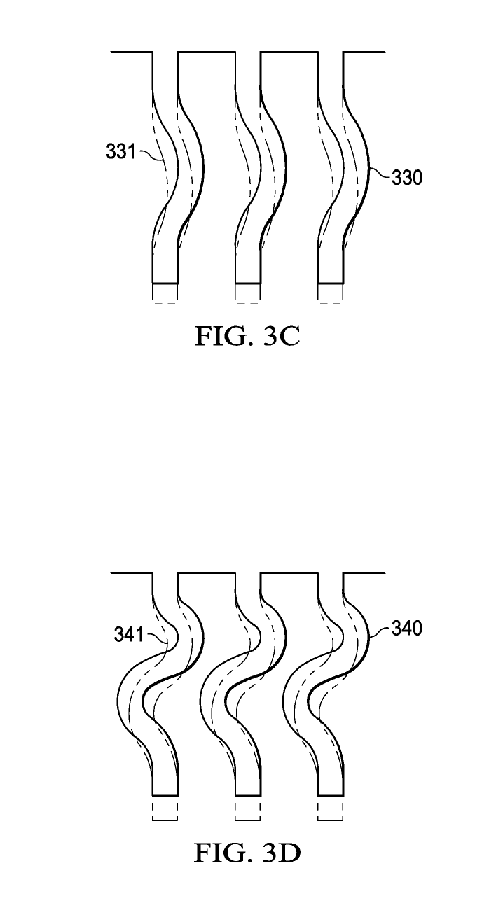

An example of a starting leadframe suitable for the forming steps of the invention is displayed in FIG. 3A, which shows an individual device site 300 of a leadframe strip for 16-pin semiconductor devices. The starting leadframe is made of a flat sheet of metal generally in a first horizontal plane. In the example of FIG. 3A, the leadframe provides a stable support pad 301, generally referred to as chip mount pad, for firmly positioning the semiconductor chip 101; as FIG. 1A shows, the attachment of chip 101 onto pad 301 is achieved by chip attach compound 102, preferably a polymeric formulation. In FIG. 3A, pad 301 is fastened to rails 303 by straps 302. Since the leadframe including pad 301 is made of electrically conducting material, the pad may be biased, when needed, to any electrical potential required by the network involving semiconductor device 101, especially the ground potential.

The leadframe offers a plurality of conductive leads to bring various electrical conductors with their central ends into close proximity of pad 301 and chip 101. The leads are elongated and generally oriented from the central region of the leadframe towards the peripheral regions; for many devices, the leads appear radial. The lead ends in the central leadframe region are referred to as central leads; they are in a first horizontal plane 150, which is the plane of the original metal sheet from which the leadframe had been fabricated. When the leadframe includes a chip pad (designated 301 in FIG. 3), this pad is in proximity of the central lead ends; the remaining gaps between the central ends of the leads and chip terminals 106 are for many device types bridged by the span of thin bonding wires 130, which electrically connect chip terminals 106 to respective central lead ends. In contrast to the central ends of the leads in proximity to the leadframe pad, the lead ends remote from the pad are referred to as peripheral ends.

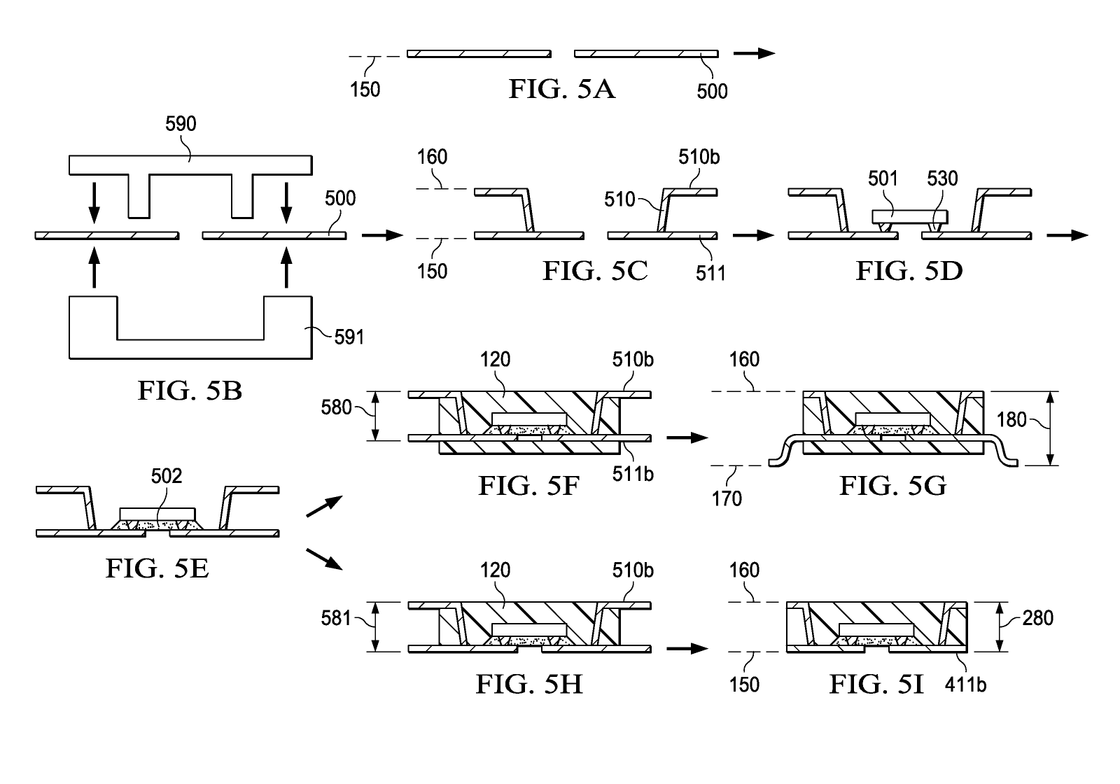

Alternatively, in other device types the electrical connections between chip terminals 106 and respective central lead ends are established by solder bumps. The solder bump method is commonly referred to as flip-chip technology, since chip 101 has to be flipped to bring the solder bumps, pre-attached to chip terminals 106, in contact with respective central lead ends of first and second leads (see process flow of FIGS. 5A to 5I). Leadframes intended for flip-chip assembly do not need a chip mount pad 301.

The plurality of leads of the exemplary leadframe in FIG. 3A is grouped in first leads 310 and second leads 311. Other devices may have any other combination, array and positioning of first and second leads. First leads 310 have their peripheral ends 310b in a second horizontal plane 160 spaced from the first plane 150, as illustrated in FIG. 1A; on the other hand, central ends 310a are, for the device example of FIG. 1A, in the first plane 150. Second leads 311 have their peripheral ends 311b in a third horizontal plane 170; on the other hand, central ends 311a are, for the device example of FIG. 1A, in the first plane 150.

As FIG. 1A shows, package 120 encapsulates chip 101, wire bonds 130, central ends 310a of the first leads, and central lead ends 311a of the second leads. Package 120 leaves the peripheral ends 310b of the first leads and the peripheral ends 311b of the second leads un-encapsulated. Since lead ends 310b are in the second horizontal plane 160 and lead ends 311b are in the third horizontal plane 170, packaged device 100 is equipped with terminals in two different planes (160 and 170). As a consequence for the example of FIG. 1A, packaged device 100 has terminals on the top and at the bottom of the package and is thus adapted for stacking semiconductor devices.

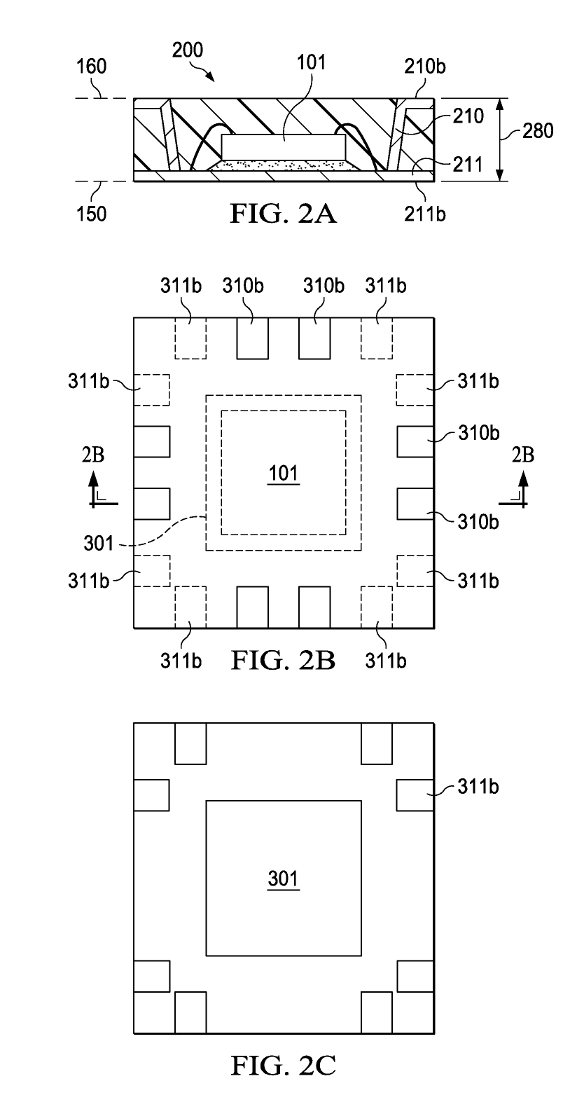

Another embodiment of a packaged device 200 with terminals in two different planes 150 and 160, and thus adapted for stacking semiconductor devices, is shown in FIG. 2A. First leads 210 and second leads 211 have their central ends in first horizontal plane 150. However, while the first leads 210 have their peripheral ends 210b in second horizontal plane 150, the second leads 211 have their peripheral ends 211b in the same first horizontal plane 150 as the central ends; the second leads 211 remain flat. Comparing device 100 and device 200, the third horizontal plane 170, separate from first horizontal plane 150 in device 100, coincides with the first horizontal plane 150 in device 200.

For manufacturing leadframes in mass production, the complete pattern of chip pad, leads and support structures is preferably stamped or etched out of the original flat thin sheet of metal; preferred thicknesses are selected from a range between about 0.15 mm to 0.25 mm. Starting materials include, but are not limited to, copper, copper alloys, aluminum, iron-nickel alloys, and Kovar™. It is preferred for some devices that the central lead ends have metallurgical surfaces suitable stitch bonding; for other device types it is preferred that the central lead ends are suitable for solder attachment. The lead portions encapsulated by packaging compound 120 have preferably a metallurgical surface suitable for adhesion to plastic or ceramic compounds, especially to molding compounds. The peripheral leadframe ends not covered by encapsulation compound have preferably metallurgical surfaces suitable for attachment to external parts, preferably using a solder technology.

For technical reasons of wire bonding, it is often desirable to position the chip mount pad in a fourth horizontal plane slightly offset (about 10 to 20 μm) from the first plane 150 of the central lead ends; the fourth horizontal plane is not indicated in FIG. 1A. Consequently, the pad straps (designated 302 in FIG. 3A) which connect the chip mount pad with the frame may be formed to accommodate the required step between the two planes. This forming is accomplished by an outside force acting on those straps. As a result, those straps become a plurality separate from the original plurality of leads. The mechanical rigidity of the chip mount pad remains unchanged.

By way of explanation, an outside force, applied along the length of the lead, can stretch the lead in the direction of the length, while the dimension of the width is only slightly reduced, so that the new shape appears elongated. For elongations small compared to the length, and up to a limit, called the elastic limit given by the material characteristics, the amount of elongation is linearly proportional to the force. Beyond that elastic limit, the lead would suffer irreversible changes and damage to its inner strength and would eventually break. The approach of limited lengthening is sometimes called the elongation-only solution. Extending a leadframe lead to distances larger than 20 μm while staying within the limits of material characteristics may be accomplished when the distance can be bridged by the lead at an inclination angle of about 30° or less. For instance, with copper as the base of the starting sheet material (thickness range 120 to 250 μm), appropriate copper alloys combined with suitable thermal treatment can be selected so that leadframes with straight leads may be designed capable of sustaining forced stretches to cover 400 to 500 μm at angles of 30° or less. If necessary, a multi-step configuration at angles of 40° or less can be adopted for covering such distances (as a side benefit, multi-step configurations may enhance mold locking of plastic to the leadframe in transfer-molded plastic packages).

For embodiments having first leads 310 with high distances between the first and second planes, and for embodiments requiring first leads with sharp bendings (>30°) and steep steps, the first leads 310 may be designed with a twofold approach for the elongation-only solution, illustrated in FIGS. 3B, 3C, and 3D, namely linearizing a designed-in lead bending together with stretching through forming. The contribution of linearizing can be obtained when a topologically long lead is first designed so that it contains toroidal geometries (designated 320 in FIG. 3B), curves and bendings (designated 330 in FIG. 3C), meanderings (designated 340 in FIG. 3D), or similar non-linearities. By applying force, at least part of the non-linearities is stretched or straightened so that afterwards the body is elongated. The change of shape is indicated by dashed lines in FIGS. 3B (321), 3C (331), and 3D (341). The process step of forming the lead uses a force, which has a vertical component causing bending, and a horizontal component causing the elongation. As stated above, the horizontal component, applied along the length of lead, stretches the lead in the direction of the length, while the dimension of the width is only slightly reduced, so that the new shape appears slightly elongated (<8%). Additional force stretches the non-linear lead portions, gaining additional elongation safely below the elastic limit of the lead material.

FIG. 1A illustrates that the peripheral ends 311b of second leads 131 are formed as cantilever leads. The total height 180 of device 100 may be any standard thickness of SOIC devices; as an example, height 180 of device 100 together with bent leads 311 may be approximately 1 mm. Height 180 is the total distance between second horizontal plane 160 and third horizontal plane 170. Preferably peripheral ends 311b have a metallurgical surface suitable for solder attachment to external parts such as a substrate. The un-encapsulated peripheral ends 311b of second leads 311 are bent into spring-like cantilevers connecting form the first to the third horizontal plane. The cantilever shape can accommodate, under a force lying in plane 170 of the expanding and contracting substrate, spring-like elastic stretching and contracting, and can thus absorb thermo-mechanical stress.

Bottom view of device 200 in FIG. 2C shows that the flat leadframe metal exposed in first plane 150, especially chip pad 301, allows not only excellent heat dissipation from chip 101 to an external heat sink, but also a reduced package dimension 280 compared to larger thickness 180 of the device in FIG. 1A.

The material of substrate 160, while generally insulating, depends on the application of device 100; as an example of the application, infrared-sending MEMS are used in ever increasing numbers for industrial purposes such as automotive and household applications. These applications are characterized by wide and often rapid temperature swings, for instance from sub-zero temperatures to more temperatures well above 100° C. In order to keep the cost of sensor MEMS low, preferred substrate selections for industrial applications include plastic and ceramic materials. Given the wide temperature variations in industrial applications, the selection of plastic and ceramic materials for substrate 160 represents a challenge for the reliability of the sensor MEMS devices 100 due to the thermo-mechanical stress caused by the much higher coefficient of thermal expansion (CTE) of the substrate materials compared to the CTE of the silicon chip 101 of the MEMS (typically about one order of magnitude or more). The methodology to construct the cantilever leads 131 as stress-absorbing compliant barriers between the silicon-based MEMS and the substrate 160 is discussed below.

Chip 101 has the opening 104 of cavity 102 facing away from the surface 101a of chip 101 and the top side of device 100. In the exemplary embodiment of FIG. 1, located inside cavity 102 is MEMS 105, preferably a radiation sensor. Exemplary sensors may be selected from a group responsive to electro-magnetic radiation, such as visible or infrared light. A preferred example as sensor in FIG. 1 is a digital infrared (IR) temperature sensor including a thermopile (multiple thermo-elements) of bismuth/antimony or constantan/copper pairs on a sensor membrane 105. The membrane is suspended in cavity 102 created by anisotropic silicon wet etching through a grid of holes (hole diameter about 18 μm, hole pitch about 36 μm center-to-center) in the membrane.

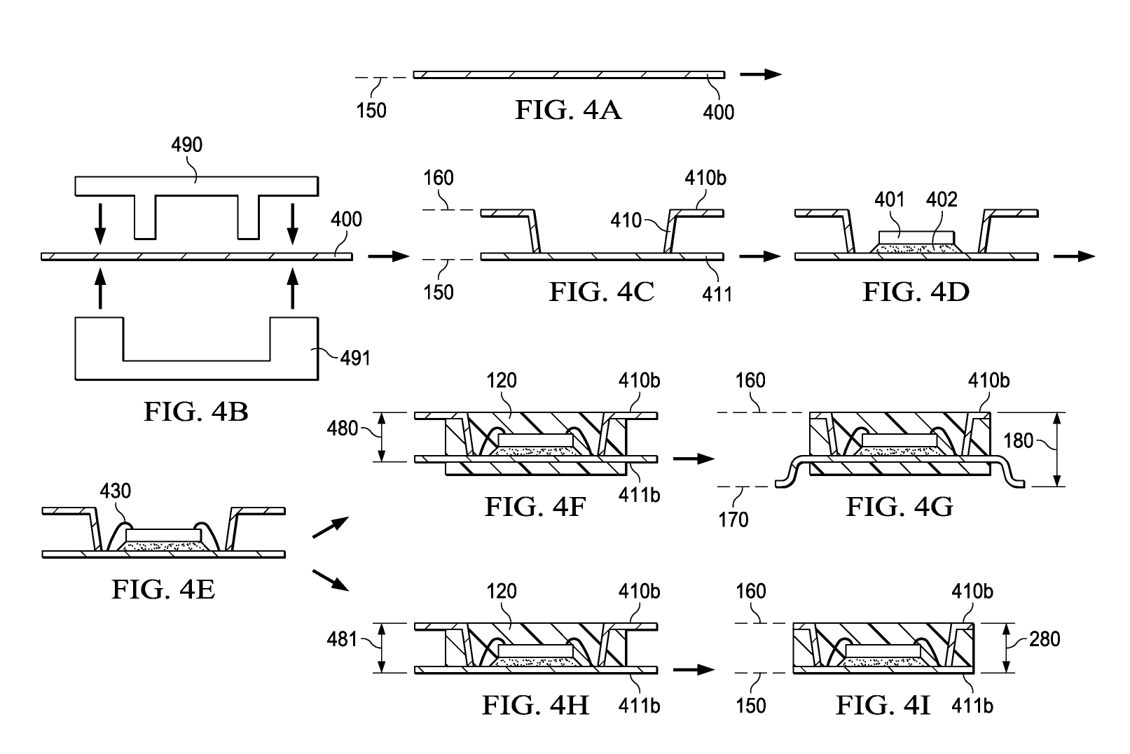

Other embodiments of the invention are methods for fabricating a leadframe-based packaged semiconductor device with package terminals on top and on bottom package surfaces. FIGS. 4A to 4I show certain steps of a process flow for a wire-bonded chip; FIGS. 5A to 5I show certain steps of a process flow for flipped chip with solder bumps. As indicated in FIGS. 4A and 5A, the method starts by providing metal strips (400, 500 respectively), which are sheet-like and flat in a first horizontal plane 150. The leadframe metal is preferably selected from a group including copper, aluminum, alloys thereof, iron-nickel alloys, and Kovar™; preferred thicknesses are selected from a range between about 0.15 to 0.25 mm. The strips are suitable for stamping or etching the features for leadframes suitable for use in semiconductor devices. Preferably, the strips include a plurality of device sites, which can be singulated at the end of the process flow. Each device site has a central region and peripheral regions. The leadframe of each device site includes first and second leads, which have ends towards the site center, and are thus in the first horizontal plane, as well as ends towards the site periphery.

The next process step is a first forming step illustrated schematically in FIGS. 4B and 5B. Strips 401 and 501 are placed in a forming machine composed of a top half (480 and 580 respectively) and a bottom half (481 and 581 respectively). The halves of the forming tool can be moved against each other so that they bend the first leads (410, 510 respectively) of each device site of the leadframe strip. The result of the bending is shown in FIGS. 4C and 5C: The peripheral ends (410b, 510b respectively) of the first leads are positioned in a second horizontal plane 160 spaced from the first horizontal plane 150; on the other hand, the second leads (411, 511 respectively) remain in the first horizontal plane 150.

In the next process step, shown in FIGS. 4D and 4E, and 5D and 5E, a semiconductor chip (401, 501) is connected to the central lead ends of each site. For the method depicted in FIGS. 4D and 4E, the leadframe has a chip mount pad near the central lead ends, and the step of connecting includes the step of attaching chip 401 to the leadframe mount pad (see FIG. 4D) using a chip attach compound 402 made of a polymeric formulation. After partial polymerization, the terminals of chip 401 are bonded by wire spans 430 to the central lead ends (see FIG. 4E). For the method depicted in FIGS. 5D and 5E, chip 501 has terminals with solder bumps 530. The chip is flipped and the bumps are attached to the central lead ends by a solder reflow process (see FIG. 5D). It is preferred that the space between the bumps of the attached chip is underfilled with a polymeric compound 502 for relieving thermo-mechanical stress on the bumps.

The sequence e of the following process steps depends on the need for, or the lack of, a second forming step for the sites of a leadframe strip. When a second forming step is required, exemplary process steps depicted in FIGS. 4F and 5F, respectively, encapsulate the assembled chips and the central lead ends of the first and second leads of each site in a packaging material 120, which also encapsulates the chip pad, but leaves the peripheral lead ends of the first and second leads un-encapsulated. The resulting package thickness is designated 480 in FIG. 4F, and 580 in FIG. 5F. The preferred encapsulation material is an epoxy-based molding compound. The un-encapsulated peripheral first lead ends are designated 410b and 510b, respectively, and the un-encapsulated peripheral second lead ends are designated 411b and 511b, respectively.

From the configuration in FIGS. 4F and 5F, the products proceed to a trimming step and a second forming step as summarized in FIGS. 4G and 5G respectively. By the trimming process, any tips of lead ends 410b and 510b, which protrude over the package contours, are cut off. It is preferred that in the same machine the leadframe strip is trimmed to singulate the sites so that in this step discrete devices are created, which have lead ends as package terminals on first plane 150 and second plane 160. After the singulation step, the discrete devices are subjected to a second forming step, which comprises bending the un-encapsulated second leads (411b and 511b, respectively) to position the peripheral ends of the second leads in a third horizontal plane 170 spaced from the first and the second plane. After the second forming step, the preferred shape is gull-wing (see FIGS. 4G and 5G) as commonly used in SOIC packages. Alternatively, J-shaped leads may be created by the second forming step, as commonly used in SOJ packages.

When no second forming step is required, exemplary process steps depicted in FIGS. 4H and 5H, respectively, encapsulate the assembled chips and the central lead ends of the first and second leads of each site in a packaging material 120, but leaves the peripheral lead ends of the first and second leads and the chip pad un-encapsulated. The resulting package thickness is designated 481 in FIG. 4H, and 581 in FIG. 5H. Thickness 481 is smaller than thickness 480, and thickness 581 is smaller than thickness 580. The preferred encapsulation material is an epoxy-based molding compound. The un-encapsulated peripheral first lead ends are designated 410b and 510b, respectively, and the un-encapsulated peripheral second lead ends are designated 411b and 511b, respectively.

From the configuration in FIGS. 4H and 5H, the products proceed to a trimming step as summarized in FIGS. 4I and 5I respectively. By the trimming process, any tips of lead ends 410b and 510b, and 411b and 511b, which protrude over the package contours, are cut off. It is preferred that in the same machine the leadframe strip is trimmed to singulate the sites so that in this step discrete devices are created, which have lead ends as package terminals on first plane 150 and second plane 160. Products as in FIGS. 4I and 5I have package outlines of QFN and SON devices with the added capability of forming package-on-package (PoP) structures.

It is a technical advantage that the exposed package terminals on the second horizontal plane 160 can be used to stack passive components such as capacitors, resistors, and inductors on top of the packaged device; in addition, other semiconductor packages may be stacked in 3D-arrangements.

It is another technical advantage that the number of exposed terminals can easily be adjusted, fir instance by depopulation, to satisfy special needs such as reducing the antenna effect.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the invention applies to products using any type of semiconductor chip, discrete or integrated circuit, and the material of the semiconductor chip may comprise silicon, silicon germanium, gallium arsenide, or any other semiconductor or compound material used in integrated circuit manufacturing. It is therefore intended that the appended claims encompass any such modifications or embodiment.

1. A semiconductor device comprising:
a leadframe having first and second leads with central and peripheral ends, the central ends in a first horizontal plane, the first leads having peripheral ends in a second horizontal plane spaced from the first plane and the second leads having peripheral ends in a third horizontal plane;
a semiconductor chip connected to the central lead ends; and
a package encapsulating the chip and the central ends of the first and second leads, leaving the peripheral ends of the first and second leads un-encapsulated, wherein the packaged device has lead ends as terminals on the second and third horizontal plane.

2. The device of claim 1 wherein the chip is connected by solder bumps to the central ends of the first and second leads.

3. The device of claim 1 wherein the chip is assembled on a mount pad near the central lead ends and connected to the central lead ends by bonding wires.

4. The device of claim 3 wherein the mount pad is in the first horizontal plane.

5. The device of claim 3 wherein the mount pad is in a fourth horizontal plane spaced from the first horizontal plane.

6. The device of claim 1 wherein the third horizontal plane is spaced from the first horizontal plane and from the second horizontal plane.

7. The device of claim 1 wherein the third horizontal plane is identical with the first horizontal plane.

8. The device of claim 1 wherein the first leads connect from the first to the second horizontal plane in a configuration accommodating, under a force normal to the first plane, elastic bending and stretching beyond the limit of simple elongation based upon inherent material characteristics.

9. The device of claim 8 wherein the configuration is selected from a group including straight geometry, curved geometry, toroidal geometry, and multiple bendings geometry.

10. The device of claim 1 wherein the un-encapsulated peripheral ends of the second leads are bent into spring-like cantilevers connecting from the first to the third plane.

11. A method for fabricating a packaged semiconductor device comprising the steps of:
providing a leadframe strip being flat in a first horizontal plane, the strip including a plurality of device sites having first and second leads with ends towards the site center and ends towards the site periphery;
bending, in a first forming step, the first leads of each site to position the peripheral ends in a second horizontal plane spaced from the first plane, while leaving the central ends in the first plane;
connecting a semiconductor chip to the central lead ends of each site;
encapsulating the strip with the assembled chips and the central ends of the first and second leads of the sites in a packaging material, while leaving the peripheral ends of the first and second leads un-encapsulated; and
trimming the strip to singulate the sites, thereby creating discrete devices having lead ends as terminals on the first and second plane.

12. The method of claim 11 wherein the step of connecting includes the steps of:
attaching the chip to a leadframe mount pad near the central lead ends; and
bonding the chip terminals with wires to the central lead ends.

13. The method of claim 11 wherein the step of connecting includes the steps of:
attaching the chip terminals with solder bumps to the central lead ends; and
under-filling the attached chip with polymeric material.

14. The method of claim 11 further including, after the step of trimming, a second forming step of each discrete device comprising bending the un-encapsulated second leads to position the peripheral ends of the second leads in a third horizontal plane spaced from the first and the second plane.

15. The method of claim 11 wherein the leadframe is selected from a group including copper, aluminum, alloys thereof, iron-nickel alloys, and Kovar™.

16. The method of claim 11 wherein the packaging material is a polymeric molding compound.
